(19) United States
(12) Patent Application Publication
(10) Pub. No.: US 2026/0177871 A1
(43) Pub. Date: Jun. 25, 2026

(54) Display Substrate and Preparation Method Therefor, and Display Device

(71) Applicants: Yunnan Invensight Optoelectronics Technology Co., Ltd., Kunming, Yunnan (CN); BOE Technology Group Co., Ltd., Beijing (CN); Beijing BOE Technology Development Co., Ltd., Beijing (CN)

(72) Inventor: Zongshun YANG, Beijing (CN)

(21) Appl. No.: 18/711,631

(22) PCT Filed: Apr. 28, 2023
(86) PCT No.: PCT/CN2023/091530

§ 371 Date: May 20, 2024

(51) Int. Cl. G02F 1/1368

(52) U.S. Cl. CPC G02F 1/1368

(57) ABSTRACT

A display substrate and a preparation method therefor, and a display device are provided. The display substrate includes a light concentrating layer (106) disposed on a side of a color film layer (105) away from the base substrate (101). The light concentrating layer (106) includes at least two adjacent convex lenses, at least one of the two adjacent convex lenses including a first lens portion (411) and a second lens portion (412) disposed sequentially in a direction away from the base substrate (101), a the second lens portion (412) is hemispherical. Orthographic projections of the two adjacent convex lenses on the base substrate (101) overlap with orthographic projections of different filter patterns on the base substrate (101). A gap is included between the two adjacent convex lenses, and at least one gap includes a curved groove (82) on a side close to a convex lens.

### CROSS-REFERENCE TO RELATED APPLICATION

The present application is a U.S. National Phase Entry of International Application No. PCT/CN2023/091530 having an international filing date of Apr. 28, 2023. Contents of the above-identified application are incorporated into the present application by reference.

### TECHNICAL FIELD

The present disclosure relates to, but is not limited to, the field of display technologies, and in particular to a display substrate and a preparation method therefor, and a display device.

### BACKGROUND

A Micro Organic Light-Emitting Diode (MicroOLED) is a micro-display that has been developed in recent years, which is also called a silicon-based OLED. The silicon-based OLED may not only realize active addressing of pixels, but also realize preparing a variety of functional circuits including timing control (TCON) circuit, over-current protection (OCP) circuit, or the like, on a silicon-based base substrate, which is conducive to reducing system size and realizing light weight. Silicon-based OLEDs are manufactured using mature complementary metal oxide semiconductor (CMOS) integrated circuit technologies, have advantages such as small size, high pixels per inch (PPI), high refresh rate and are widely used in near-to-eye display fields of virtual reality (VR) or augmented reality (AR).

A silicon-based OLED generally cannot achieve high display brightness, thus the display effect of the silicon-based OLED is poor.

### SUMMARY

The following is a summary of subject matters described herein in detail. This summary is not intended to limit the protection scope of the claims.

In a first aspect, the present disclosure provides a display substrate, which includes: a base substrate; a light emitting device disposed on a side of the base substrate, the light emitting device being configured to emit light; a color film layer disposed on a side of the light emitting device away from the base substrate, the color film layer including at least two filter patterns; at least portions of adjacent filter patterns being stacked in a thickness direction of the base substrate to form an overlap portion; and a light concentrating layer disposed on a side of the color film layer away from the base substrate, the light concentrating layer being configured to concentrate light emitted from the color film layer.

The light concentrating layer includes at least two adjacent convex lenses, at least one of the two adjacent convex lenses includes a first lens portion and a second lens portion disposed sequentially in a direction away from the base substrate, and the second lens portion is hemispherical. Orthographic projections of the two adjacent convex lenses on the base substrate overlap with orthographic projections of different filter patterns on the base substrate. A gap is included between the two adjacent convex lenses, at least one gap includes a curved groove on a side close to a convex lens, and a gap between the orthographic projections of the two adjacent convex lenses on the base substrate is located in an orthographic projection of the overlap portion on the base substrate.

In some embodiments, the following relationship is satisfied between a curvature radius R1 of the curved groove and a curvature radius R2 of the convex lens on the same side: 4.5≤R2/R1≤15.

In some embodiments, in the thickness direction of the base substrate, a minimum spacing between a bottom end of the curved groove and an edge of the convex lens on the same side is smaller than a minimum spacing between the orthographic projections of the two adjacent convex lenses on the base substrate.

In some embodiments, a minimum spacing L1 between the orthographic projections of the two adjacent convex lenses on the base substrate is less than or equal to 0.8 microns and greater than or equal to 0.2 microns.

In some embodiments, an orthographic projection of the gap between the two adjacent convex lenses on the base substrate is located in an orthographic projection of the overlap portion on the base substrate.

In some embodiments, the two adjacent convex lenses include a first convex lens and a second convex lens, the first convex lens including a first lens portion and a second lens portion disposed sequentially in a direction away from the base substrate, the second lens portion being hemispherical, the second convex lens including a circular bottom surface, the second convex lens having a maximum thickness less than or equal to a radius of the circular bottom surface.

In some embodiments, a maximum thickness of the first convex lens is greater than the maximum thickness of the second convex lens.

In some embodiments, the difference between the maximum thickness of the first convex lens and the maximum thickness of the second convex lens is from 0.4 microns to 0.6 microns.

In some embodiments, a maximum thickness of the first convex lens is 2.1 times to 2.5 times a radius of a bottom surface of the first convex lens on a side close to the base substrate.

In some embodiments, the two adjacent convex lenses include a first convex lens and a second convex lens. The first convex lens includes a first lens portion and a second lens portion. The second convex lens includes a third lens portion and a fourth lens portion disposed sequentially in a direction away from the base substrate, and the fourth lens portion is hemispherical.

In some embodiments, areas of the orthographic projections of the two adjacent convex lenses on the base substrate are different.

In some embodiments, the color film layer includes a first filter pattern, a second filter pattern and a third filter pattern. The first filter pattern is adjacent to the second filter pattern, and at least a portion of the first filter pattern and at least a portion of the second filter pattern are stacked in a thickness direction of the base substrate to form a first overlap portion, in which the first filter pattern is located on a side of the second filter pattern away from the base substrate. The second filter pattern is adjacent to the third filter pattern, and at least a portion of the second filter pattern and at least a portion of the third filter pattern are stacked in the thickness direction of the base substrate to form a second overlap portion, in which the second filter pattern is located on a side of the third filter pattern away from the base substrate.

In some embodiments, the first lens portion and the second lens portion are of an integral structure.

In some embodiments, the first lens portion includes a first surface on a side close to the base substrate, a second surface on a side away from the base substrate, and a side surface connecting the first surface and the second surface, the second surface is a surface of the second lens portion on a side close to the base substrate, and the side surface is arc-shaped.

In some embodiments, an included angle between a tangent at an intersection of the side surface and the first surface and a plane parallel to the base substrate is less than 90 degrees and greater than or equal to 30 degrees.

In some embodiments, a distance between the first surface of the first lens portion and the second surface of the first lens portion is from 300 nm to 600 nm.

In some embodiments, a flat layer is also included, and the flat layer is positioned between the color film layer and the light concentrating layer. A refractive index of a material of the flat layer is not greater than that of a material of the light concentrating layer.

In some embodiments, a maximum thickness of the second lens portion is greater than a maximum thickness of the first lens portion in a direction perpendicular to the base substrate.

In some embodiments, a minimum distance between the orthographic projections of the two adjacent convex lenses on the base substrate is greater than or equal to a maximum thickness of the first lens portion.

In another aspect, the present disclosure also provides a display device, including the display substrate described above.

In another aspect, the present disclosure further provides a preparation method for a display substrate, including: forming a light emitting device on a base substrate; forming a color film layer on the light emitting device, the color film layer including at least two filter patterns, at least portions of adjacent filter patterns being stacked in a thickness direction of the base substrate to form an overlap portion; and forming a light concentrating layer on the color film layer, the light concentrating layer being configured to concentrate light emitted from the color film layer.

The light concentrating layer includes at least two adjacent convex lenses, at least one of the two adjacent convex lenses includes a first lens portion and a second lens portion disposed sequentially in a direction away from the base substrate, and the second lens portion is hemispherical. Orthographic projections of the two adjacent convex lenses on the base substrate overlap with orthographic projections of different filter patterns on the base substrate. A gap is included between the two adjacent convex lenses, at least one gap includes a curved groove on a side close to a convex lens, and a gap between the orthographic projections of the two adjacent convex lenses on the base substrate is located in an orthographic projection of the overlap portion on the base substrate.

Other aspects may become clear after the accompanying drawings and the detailed description are read and understood.

### BRIEF DESCRIPTION OF DRAWINGS

Accompanying drawings are used for providing an understanding of technical solutions of the present application and form a part of the specification, are used for explaining the technical solutions of the present application together with embodiments of the present application, and do not constitute a limitation on the technical solutions of the present application.

FIG. 1 is a schematic diagram of a planar structure of a display substrate;

FIG. 2 is a schematic diagram of a sectional structure of a display substrate;

FIG. 3 is a schematic diagram of a sectional structure of a display substrate according to an exemplary embodiment of the present disclosure;

FIG. 4 is a schematic diagram of a sectional structure of a color film layer and a light concentrating layer in a display substrate according to an exemplary embodiment of the present disclosure;

FIG. 5 is a first schematic diagram of a sectional structure of a light concentrating layer in a display substrate according to an exemplary embodiment of the present disclosure;

FIG. 6 is an enlarged view of a sectional structure of a light concentrating layer in a display substrate according to an exemplary embodiment of the present disclosure; and

FIG. 7 is a second schematic diagram of a sectional structure of a light concentrating layer in a display substrate according to an exemplary embodiment of the present disclosure.

### DETAILED DESCRIPTION

To make the objectives, technical solutions, and advantages of the present disclosure clearer, the embodiments of the present disclosure will be described in detail below with reference to the drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the accompanying drawings, a size of each composition element, a thickness of a layer, or a region may be exaggerated sometimes for clarity. Therefore, an implementation of the present disclosure is not always limited to the size, and the shape and size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third” and the like in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the composition elements with reference to the drawings, not to indicate or imply that involved devices or elements are required to have specific orientations or are structured and operated in the specific orientations, but only to easily describe the present specification and simplify the description, and thus should not be understood as limitations on the present disclosure. The positional relationships between the constituent elements may be changed as appropriate according to a direction in which each constituent element is described. Therefore, appropriate replacements based on situations are allowed, and the positional relationships are not limited to the expressions in the specification.

In the specification, unless otherwise explicitly specified and defined, terms “mounting”, “coupling”, and “connection” should be understood in a broad sense. For example, it may be a fixed connection, or a detachable connection, or an integral connection; it may be a mechanical connection or an electrical connection; it may be a direct connection, or an indirect connection through middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Alternatively, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the specification.

In the specification, “electrical connection” includes connection of composition elements through an element with a certain electrical action. An “element with a certain electrical action” is not particularly limited as long as electrical signals may be sent and received between the connected constituent elements. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

In the present disclosure, “about” means that a boundary is not defined so strictly and numerical values within a range of process and measurement errors are allowed.

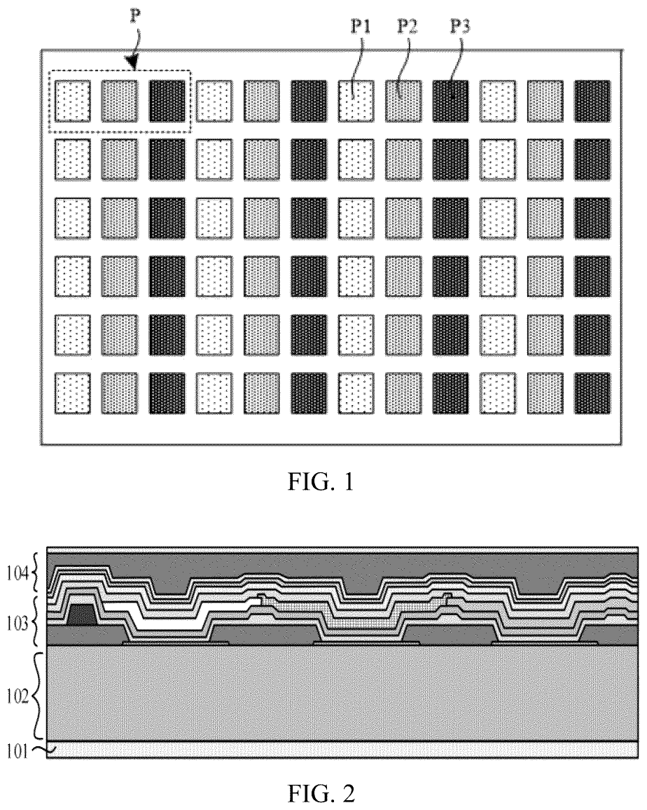

FIG. 1 is a schematic diagram of a planar structure of a display substrate. In an exemplary implementation, the display substrate may include a display area and a bezel area located on a periphery of the display area. As shown in FIG. 1, the display area of the display substrate may include multiple pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting unit. The circuit unit may at least include a pixel drive circuit. The pixel drive circuit is connected with a scan signal line, a data signal line, and a light emitting signal line respectively, and is configured to receive a data voltage transmitted by the data signal line and output a corresponding current to a light emitting device under control of the scan signal line and the light emitting signal line. The light emitting unit may at least include light emitting devices, the light emitting devices are respectively connected with pixel drive circuits of sub-pixels where the light emitting devices are located, and the light emitting devices are configured to emit light with a corresponding brightness in response to a current output by the pixel drive circuits of the sub-pixels where the light emitting devices are located. Each sub-pixel includes an opening area defining a light emitting area of the sub-pixel.

In an exemplary implementation, a display panel includes a display area having a rectangular shape. In some embodiments, the display area may also have a circular shape, an elliptical shape, or a polygonal shape such as a triangle and a pentagon.

In an exemplary implementation, the first sub-pixel P1 may be a red sub-pixel (R) emitting red light, the second sub-pixel P2 may be a blue sub-pixel (B) emitting blue light, and the third sub-pixel P3 may be a green sub-pixel (G) emitting green light. In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, or in a manner like a Chinese character “o” or other manner, which is not limited here in the present disclosure.

In an exemplary implementation, a pixel unit may include four sub-pixels, and the four sub-pixels may be arranged in a manner to stand side by side horizontally, in a manner to stand side by side vertically, or in a manner to form a square or other manner, which is not limited here in the present disclosure.

In an exemplary implementation, the light emitting device may include one of an organic light emitting diode (OLED), a light emitting diode (LED), a quantum dot light emitting diode (QLED). The sub-pixel may emit light, such as red light, green light, blue light or white light, by the light emitting device.

In an exemplary implementation, the display substrate is of a top emission type, a bottom emission type, a dual emission type or the like. In the top emission type, visible light emitted from the light emitting device can be irradiated an area in front of the display substrate to display an image. In the bottom emission type, visible light emitted from the light emitting device can be irradiated to an area behind the display substrate to display an image.

The light-emitting device in the display panel in accordance with this embodiment being an organic light-emitting diode (OLED) will be described as an example hereinafter, but the display panel in accordance with this embodiment is not limited thereto. In another embodiment, the light-emitting device in the display panel may be a micro light-emitting diode (LED) or a quantum dot light-emitting diode (QLED) or the like. For example, a light-emitting layer of the light-emitting device in the display panel may include an organic material, an inorganic material, quantum dots, an organic material and quantum dots, an inorganic material and quantum dots, or an organic material, an inorganic material and quantum dots.

FIG. 2 is a schematic diagram of a sectional structure of a display substrate, and illustrates a structure of three sub-pixels of a display substrate. In an exemplary implementation, a display substrate according to an embodiment of the present disclosure may include more sub-pixels (see FIG. 1). In addition, although the three sub-pixels are shown to be adjacent to each other in FIG. 2, the embodiments of the present disclosure are not limited thereto. That is, other assemblies, for example wirings, may be between the three sub-pixels. The three sub-pixels may not be pixels adjacent to each other. In FIG. 2, cross sections of the three sub-pixels may not be cross sections in a same direction of the display substrate.

In an exemplary implementation, as shown FIG. 2, in a plane perpendicular to the display substrate, a display area of the display substrate may include a drive circuit layer 102 disposed on a base substrate 101, a light emitting structure layer 103 disposed on a side of the drive circuit layer 102 away from the base substrate 101, and an encapsulation structure layer 104 disposed on a side of the light emitting structure layer 103 away from the base substrate 101. In some possible implementations, the display substrate may include another film layer, such as a touch structure layer, which is not limited here in the present disclosure.

In an exemplary implementation, the base substrate 101 may be a flexible base substrate, or may be a rigid base substrate. The drive circuit layer 102 may include multiple circuit units, a circuit unit may at least include a pixel drive circuit, and the pixel drive circuit may include multiple transistors and a storage capacitor. The light emitting structure layer 103 may include multiple light emitting units, a light emitting unit may at least include a light emitting device, and the light emitting device may include an anode, an organic light emitting layer, and a cathode. The anode is connected with a pixel drive circuit. The organic light emitting layer is connected with the anode. The cathode is connected with the organic light emitting layer. The organic light emitting layer emits light of a corresponding color under driving of the anode and the cathode.

In an exemplary implementation, the organic light emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL).

In some exemplary embodiments, the encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer to form a stacked structure of inorganic material/organic material/inorganic material, which may ensure that external moisture cannot enter the light emitting structure layer.

An exemplary embodiment of the present disclosure provides a display substrate, including: a base substrate; a light emitting device disposed on a side of the base substrate, the light emitting device being configured to emit light; a color film layer disposed on a side of the light emitting device away from the base substrate, the color film layer including at least two filter patterns, at least portions of adjacent filter patterns being stacked in a thickness direction of the base substrate to form an overlap portion; and a light concentrating layer disposed on a side of the color film layer away from the base substrate, the light concentrating layer configured to concentrate light emitted from the color film layer.

The light concentrating layer includes at least two adjacent convex lenses, at least one of the two adjacent convex lenses includes a first lens portion and a second lens portion disposed sequentially in a direction away from the base substrate, and the second lens portion is hemispherical. Orthographic projections of the two adjacent convex lenses on the base substrate overlap with orthographic projections of different filter patterns on the base substrate. A gap is included between the two adjacent convex lenses, at least one gap includes a curved groove on a side close to a convex lens, and a gap between orthographic projections of the two adjacent convex lenses on the base substrate is located in an orthographic projection of the overlap portion on the base substrate.

In some embodiments, the following relationship is satisfied between a curvature radius R1 of the curved groove and a curvature radius R2 of the convex lens on the same side: 4.5≤R2/R1≤15.

In some embodiments, a minimum spacing between a bottom end of the curved groove and a junction of the edge of the convex lens on the same side and the curved groove is less than a minimum spacing between orthographic projections of the two adjacent convex lenses on the base substrate.

In some embodiments, the minimum spacing L1 between the orthographic projections of the two adjacent convex lenses on the base substrate is less than or equal to 0.8 microns and greater than or equal to 0.2 microns.

In some embodiments, an orthographic projection of the gap between the two adjacent convex lenses on the base substrate is located in an orthographic projection of the overlap portion on the base substrate.

The display substrate of the present disclosure is illustrated with examples below through some exemplary embodiments.

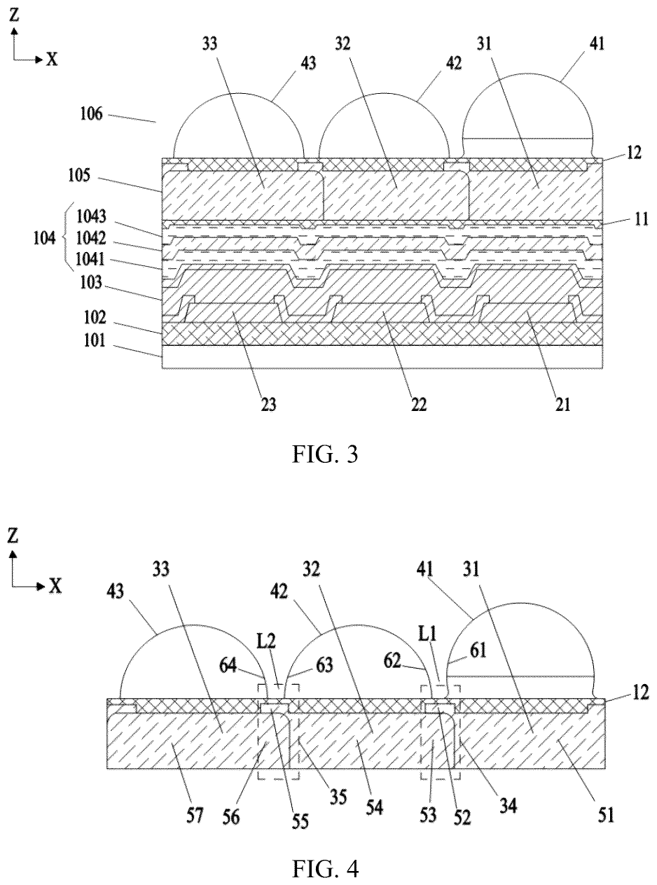

FIG. 3 is a schematic diagram of a sectional structure of a display substrate of an exemplary embodiment of the present disclosure, illustrating three sub-pixels (first sub-pixel, second sub-pixel, and third sub-pixel) in the display substrate. In an exemplary implementation, as shown in FIG. 3, the display substrate may include a base substrate 101, a drive circuit layer 102 disposed on the base substrate 101, a light emitting structure layer 103 disposed on a side of the drive circuit layer 102 away from the base substrate 101, an encapsulation structure layer 104 disposed on a side of the light emitting structure layer 103 away from the base substrate 101, a first flat layer 11 disposed on a side of the encapsulation structure layer 104 away from the base substrate 101, a color film layer 105 disposed on a side of the first flat layer 11 away from the base substrate 101, a second flat layer 12 disposed on a side of the color film layer 105 away from the base substrate 101, and a light concentrating layer 106 disposed on a side of the second flat layer 12 away from the base substrate 101. The light concentrating layer 106 can improve the light emitting efficiency and the light emitting brightness of the sub-pixels, thereby reducing the power consumption of the display substrate.

In an exemplary implementation, the drive circuit layer 102 may include at least a plurality of circuit units, and the light emitting structure layer may include at least a plurality of light emitting units. At least one circuit unit includes a pixel drive circuit. At least one light emitting unit includes a light emitting device. The light emitting device may include at least an anode, an organic light emitting layer, and a cathode, and a anode in the light emitting unit is connected to a pixel drive circuit in the corresponding circuit unit. In an exemplary implementation, the circuit units mentioned in the present disclosure refer to regions divided according to pixel drive circuits, and light emitting units mentioned in the present disclosure refer to regions divided according to light emitting devices. In an exemplary embodiment, a position of an orthographic projection of a light emitting unit on the base substrate may correspond to a position of an orthographic projection of a circuit unit on the base substrate, or a position of an orthographic projection of a light emitting unit on the base substrate may not correspond to a position of an orthographic projection of a circuit unit on the base substrate.

In an exemplary implementation, as shown in FIG. 3, the light emitting unit includes a first light emitting device 21, a second light emitting device 22, and a third light emitting device 23, which are arranged at intervals in an opposite direction of a direction X. The first light emitting device 21 may emit light of a first color such as blue light. The second light emitting device 22 may emit light of a second color such as green light. The third light emitting device 23 may emit light of a third color such as red light. The direction X is a direction parallel to a plane where the base substrate is located.

In an exemplary implementation, as shown in FIG. 3, the encapsulation structure layer 104 may include a first encapsulation layer 1041, a second encapsulation layer 1042, and a third encapsulation layer 1043 that are stacked. The first encapsulation layer 1041 and the third encapsulation layer 1043 may be made of an inorganic material, the second encapsulation layer 1042 may be made of an organic material, and the second encapsulation layer 1042 is disposed between the first encapsulation layer 1041 and the third encapsulation layer 1043 to form a laminated structure of inorganic material/organic material/inorganic material, which may ensure that external moisture cannot enter the light emitting structure layer 103.

In an exemplary implementation, as shown in FIG. 3, both the first flat layer 11 and the second flat layer 12 may be made of an organic material such as a resin. Surfaces of the first flat layer 11 and the second flat layer 12 on a side away from the base substrate 101 are flat, i.e. distances between the surfaces of the first flat layer 11 and the second flat layer 12 on a side away from the base substrate 101 and a surface of the base substrate 101 are the same or close. When a surface of a film layer located on a side of the encapsulation structure layer 104 close to the base substrate 101 is uneven, a surface of the encapsulation structure layer 104 on a side away from the base substrate 101 is uneven. The first flat layer 11 covers the uneven part of the surface of the encapsulation structure layer 104 on a side away from the base substrate 101, so that the segment difference generated at the uneven part of the encapsulation structure layer 104 can be reduced to ensure the uniformity of the display substrate. When a surface of the color film layer 105 on a side away from the base substrate 101 is uneven, the second flat layer 12 covers the uneven part of the surface of the color film layer 105 on a side away from the base substrate 101, so that the segment difference generated at the uneven part of the color film layer 105 can be reduced to ensure the uniformity of the display substrate.

In an exemplary implementation, a second flat layer 12 is located between a color film layer 105 and a light concentrating layer 106. A refractive index of the material of the second flat layer 12 is not greater than that of the material of the light concentrating layer 106, so that the light transmitted through the color film layer 105 on the surface is totally reflected at the junction of the second flat layer 12 and the color film layer 105, thus ensuring the light-emitting effect of the display substrate.

In an exemplary implementation, as shown in FIG. 3, the color film layer 105 includes a first filter pattern 31, a second filter pattern 32, and a third filter pattern 33, which are arranged at intervals in the opposite direction of the direction X. The first filter pattern 31 is configured to allow light of a first color to be emitted, for example blue light, and an orthographic projection of the first filter pattern 31 on the base substrate overlaps with an orthographic projection of the first light emitting device 21 on the base substrate, for example, the orthographic projection of the first light emitting device 21 on the base substrate is located in the orthographic projection of the first filter pattern 31 on the base substrate. The second filter pattern 32 is configured to allow light of a second color to be emitted, such as green light, and an orthographic projection of the second filter pattern 32 on the base substrate overlaps with an orthographic projection of the second light emitting device 22 on the base substrate, for example, the orthographic projection of the second light emitting device 22 on the base substrate is located in the orthographic projection of the second filter pattern 32 on the base substrate. The third filter pattern 33 is configured to allow light of a third color to be emitted, for example red light, and an orthographic projection of the third filter pattern 33 on the base substrate overlaps with an orthographic projection of the third light emitting device 23 on the base substrate, for example, the orthographic projection of the third light emitting device 23 on the base substrate is located in the orthographic projection of the third filter pattern 33 on the base substrate.

In an exemplary implementation, as shown in FIG. 3, within the same light emitting unit, the light concentrating layer 106 includes a first convex lens 41, a second convex lens 42, and a third convex lens 43, which are arranged in the opposite direction of the direction X. The first convex lens 41 is configured to concentrate light emitted from the first filter pattern 31 and refract a large angle light emitted from the first filter pattern 31 to form a small angle light, thereby achieving a light focus effect. For example, the light emitted from the first filter pattern 31 are blue light, and the first convex lens 41 can concentrate the blue light emitted from the first filter pattern 31. The second convex lens 42 is configured to concentrate light emitted from the second filter pattern 32 and refract a large angle light emitted from the second filter pattern 32 to form a small angle light, thereby achieving a light focus effect. For example, the light emitted from the second filter pattern 32 are green light, and the second convex lens 42 can concentrate the green light emitted from the second filter pattern 32. The third convex lens 43 is configured to concentrate light emitted from the third filter pattern 33 and refract a large angle light emitted from the third filter pattern 33 to form a small angle light, thereby achieving a light focus effect. For example, the light emitted from the third filter pattern 33 are red light, and the third convex lens 43 can concentrate the red light emitted from the third filter pattern 33.

In an exemplary implementation, as shown in FIG. 3, an orthographic projection of the first convex lens 41 on the base substrate overlaps with an orthographic projection of the first filter pattern 31 on the base substrate. For example, the orthographic projection of the first convex lens 41 on the base substrate is located in the orthographic projection of the first filter pattern 31 on the base substrate. An orthographic projection of the second convex lens 42 on the base substrate overlaps with an orthographic projection of the filter pattern 32 on the base substrate. For example the orthographic projection of the second convex lens 42 on the base substrate is located in the orthographic projection of the second filter pattern 32 on the base substrate. An orthographic projection of the third convex lens 43 on the base substrate overlaps with an orthographic projection of the third filter pattern 33 on the base substrate. For example, the orthographic projection of the third convex lens 43 on the base substrate is located in the orthographic projection of the third filter pattern 33 on the base substrate.

FIG. 4 is a schematic diagram of a sectional structure of a color film layer and a light concentrating layer in a display substrate according to an exemplary embodiment of the present disclosure. In an exemplary implementation, as shown in FIG. 4, at least portions of two adjacent filter patterns in the color film layer are stacked in a thickness direction of the base substrate to form an overlap portion, which may serve as a light blocking pattern to prevent color crosstalk between adjacent sub-pixels.

In an exemplary implementation, as shown in FIG. 4, the first filter pattern 31 is adjacent to the second filter pattern 32 and the second filter pattern 32 is adjacent to the third filter pattern 33. The first filter pattern 31 may include a first filter portion 51 and a second filter portion 52, and orthographic projections of the first filter portion 51 and the second filter portion 52 on the base substrate do not overlap. The second filter pattern 32 may include a third filter portion 53, a fourth filter portion 54, and a fifth filter portion 55, and orthographic projections of the third filter portion 53, the fourth filter portion 54 and the fifth filter portion 55 on the base substrate do not overlap. The third filter pattern 33 may include a sixth filter portion 56 and a seventh filter portion 57, and orthographic projections of the sixth filter portion 56 and the seventh filter portion 57 on the base substrate do not overlap. The orthographic projection of the first filter portion 51 of the first filter pattern 31 on the base substrate overlaps with the orthographic projection of the first convex lens 41 on the base substrate. The orthographic projection of the fourth filter portion 54 of the second filter pattern 32 on the base substrate overlaps with the orthographic projection of the second convex lens 42 on the base substrate. The orthographic projection of the seventh filter portion 57 of the third filter pattern 33 on the base substrate overlaps with the orthographic projection of the third convex lens 43 on the base substrate.

In an exemplary implementation, as shown in FIG. 4, orthographic projections of the second filter portion 52 of the first filter pattern 31 and the third filter portion 53 of the second filter pattern 32 on the base substrate overlap. The second filter portion 52 and the third filter portion 53 are stacked in the direction Z, and the second filter portion 52 is located on a side of the third filter portion 53 away from the base substrate. The maximum distance from a surface of the second filter portion 52 on a side away from the base substrate to a surface of the base substrate is greater than the maximum distance from a surface of the third filter portion 53 on a side away from the base substrate to the surface of the base substrate. The second filter portion 52 and the third filter portion 53 form a first overlap portion 34.

In an exemplary implementation, as shown in FIG. 4, orthographic projections of the fifth filter portion 55 of the second filter pattern 32 and the sixth filter portion 56 of the third filter pattern 32 on the base substrate overlap. The fifth filter portion 55 and the sixth filter portion 56 are stacked in the direction Z, and the fifth filter portion 55 is located on a side of the sixth filter portion 56 away from the base substrate. The maximum distance from a surface of the fifth filter portion 55 on a side away from the base substrate to a surface of the base substrate is greater than the maximum distance from a surface of the sixth filter portion 56 on a side away from the base substrate to the surface of the base substrate. The fifth filter portion 55 and the sixth filter portion 56 form a second overlap portion 35.

In an exemplary implementation, as shown in FIG. 4, the second flat layer 12 between the light concentrating layer 106 and the color film layer 105 can ensure the uniformity of the topography of each sub-pixel in the display substrate, solve the problem that a surface of the color film layer 105 on a side away from the base substrate is uneven due to the overlapping of adjacent filter patterns in the color film layer 105, and realize the uniformity of the display brightness of the display substrate.

In an exemplary implementation, as shown in FIG. 4, two adjacent convex lenses in the light concentrating layer are disposed at intervals, and a gap between orthographic projections of the two adjacent convex lenses on the base substrate is located in an orthographic projection of an overlap portion of two adjacent filter patterns on the base substrate, thereby ensuring that light emitted from the filter patterns can be concentrated through the corresponding convex lenses.

In an exemplary implementation, as shown in FIG. 4, the first convex lens 41 is adjacent to the second convex lens 42 and the second convex lens 42 is adjacent to the third convex lens 43. The first convex lens 41 includes a first side surface 61 which is a side surface of the first convex lens 41 on a side close to the second convex lens 42. The second convex lens 42 includes a second side surface 62 which is a side surface of the second convex lens 42 on a side close to the first convex lens 41 and a third side surface 63 which is a side surface of the second convex lens 42 on a side close to the third convex lens 43. The third convex lens 43 includes a fourth side surface 64 which is a side surface of the third convex lens 43 on a side close to the second convex lens 42. The minimum distance L1 between the first side surface 61 of the first convex lens 41 and the second side surface 62 of the second convex lens 42 in the direction X is the minimum spacing between the orthographic projections of the first convex lens 41 and the second convex lens 42 on the base substrate. The minimum distance L2 between the third side surface 63 of the second convex lens 42 and the fourth side surface 64 of the third convex lens 43 in the direction X is the minimum spacing between the orthographic projections of the second convex lens 42 and the third convex lens 43 on the base substrate, where L1 is smaller than L2. Exemplarily, the ratio of the minimum distance L1 to the minimum distance L2 is 1:2 to 1:5. For example, the minimum distance L1 may be 0.1 micron to 1 micron, or the minimum distance L1 may be 0.2 micron to 0.8 micron; and the minimum distance L2 may be 0.2 microns to 5 microns, or the minimum distance L2 may be 0.4 microns to 4 microns.

In an exemplary implementation, as shown in FIG. 4, the gap between the orthographic projections of the first convex lens 41 and the second convex lens 42 on the base substrate is located in an orthographic projection of the first overlap portion 34 on the base substrate, and the minimum distance L1 between the first side surface 61 of the first convex lens 41 and the second side surface 62 of the second convex lens 42 in the direction X is smaller than the minimum distance of the first overlap portion 34 in the direction X. The gap between orthographic projections of the second convex lens 42 and the third convex lens 43 on the base substrate is located in an orthographic projection of the second overlap portion 35 on the base substrate, and the minimum distance L2 between the third side surface 63 of the second convex lens 42 and the fourth side surface 64 of the third convex lens 43 in the direction X is smaller than the minimum distance of the second overlap portion 35 in the direction X.

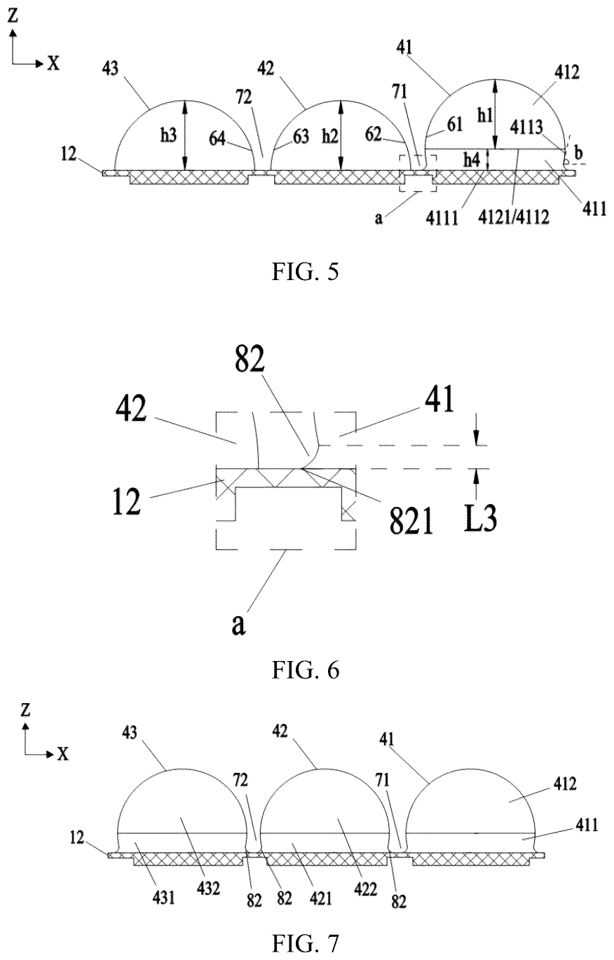

FIG. 5 is a first schematic diagram of a sectional structure of a light concentrating layer in a display substrate according to an exemplary embodiment of the present disclosure. In an exemplary implementation, as shown in FIG. 5, the second convex lens 42 includes a second circular bottom surface and a second circular arc surface disposed on the second circular bottom surface, and the third convex lens 43 includes a third circular bottom surface and a third circular arc surface disposed on the third circular bottom surface. The maximum thickness h2 of the second convex lens 42 is less than or equal to the radius of the second circular bottom surface of the second convex lens 42. For example, the second convex lens 42 is hemispherical, the maximum thickness h2 of the second convex lens 42 is equal to the radius of the second circular bottom surface of the second convex lens 42, and a tangent at the junction of the second circular arc surface and the second circular bottom surface is perpendicular to the second circular bottom surface of the second convex lens 42. The maximum thickness h3 of the third convex lens 43 is less than or equal to the radius of the third circular bottom surface of the third convex lens 43. For example, the third convex lens 43 is hemispherical, the maximum thickness h3 of the third convex lens 43 is equal to the radius of the third circular bottom surface of the third convex lens 43, and a tangent at the junction of the third circular arc surface and the third circular bottom surface is perpendicular to the third circular bottom surface of the third convex lens 43.

In an exemplary implementation, both the second convex lens 42 and the third convex lens 43 are hemispherical, which can ensure that light emitted from the filter patterns corresponding to the second convex lens 42 and the third convex lens 43 are concentrated through the second convex lens 42 and the third convex lens 43, thereby achieving higher display brightness.

In an exemplary implementation, as shown in FIG. 5, the first convex lens 41 includes a first lens portion 411 and a second lens portion 412 stacked sequentially in a direction away from the base substrate. The second lens portion 412 is hemispherical. The second lens portion 412 includes a first circular bottom surface 4121 and a hemispherical surface disposed on the first circular bottom surface 4121, the first circular bottom surface 4121 of the second lens portion 412 may be a surface of the first lens portion 411 away from the base substrate, and a tangent of the junction of the hemispherical surface and the first circular bottom surface 4121 is perpendicular to the first circular bottom surface 4121.

In an exemplary implementation, the maximum thickness of the first convex lens 41 is greater than or equal to the maximum size of the bottom surface of the first convex lens 41 on a side close to the base substrate. For example, the maximum thickness of the first convex lens 41 is 2.1 to 2.5 times the radius of the bottom surface of the first convex lens 41 on a side close to the base substrate.

In an exemplary implementation, as shown in FIG. 5, the first lens portion 411 is located on a side of the second lens portion 412 close to the base substrate, and the first lens portion 411 includes a first surface 4111 and a second surface 4112 disposed opposite to each other, and a side surface 4113 connecting the first surface 4111 and the second surface 4112. The first surface 4111 is a surface of the first lens portion 411 on a side close to the base substrate and is in contact with a surface of the second flat layer 12. The second surface 4112 is a surface of the first lens portion 411 on a side away from the base substrate, and the second surface 4112 is a first circular bottom surface 4121 of the second lens portion 412. The side surface 4113 is arc-shaped, and an included angle b between a tangent of an end of the side surface 4113 on a side close to the second flat layer 12 and a plane where the base substrate is located is less than 90 degrees and greater than or equal to 30 degrees.

In an exemplary implementation, the maximum thickness of the second lens portion 412 is greater than the maximum thickness of the first lens portion 411 in a direction perpendicular to the base substrate.

In an exemplary implementation, the minimum distance between orthographic projections of two adjacent convex lenses on the base substrate is greater than or equal to the maximum thickness of the first lens portion 411, thereby avoiding the reduction of a light focus effect caused by the excessive thickness of the first lens portion, while improving the process effect and the stability of the structure of the lens.

For example, a distance between the first surface 4111 of the first lens portion 411 and the second surface 4112 of the first lens portion 411 is 300 nm to 600 nm.

In the process of preparing convex lens, exposure, thermal melting and other processes are needed, so the process is difficult to control. If the process fluctuates slightly, such as exposure focusing fluctuation, the position of the circular bottom surface of convex lens may move down, resulting in the inability to form hemispherical convex lens. That is, the radius of the circular bottom surface of convex lens is larger than the maximum thickness of convex lens, resulting in a part of light emitted by its corresponding filter pattern not passing through convex lens, which reduces the light efficiency gain effect of convex lens.

In the display substrate according to an embodiment of the present disclosure, the first convex lens 41 includes a first lens portion 411 and a second lens portion 412, the first lens portion 411 is hemispherical, and the circular bottom surface of the first lens portion 411 is raised by a certain height during the preparation of the first convex lens 41, i.e. the first lens portion 411 is disposed on the second lens portion 412, thereby solving the problem that at least part of the first convex lens 41 cannot form a hemispherical shape due to fluctuations in the preparation process, ensuring the light efficiency gain effect of the first convex lens 41 and achieving higher display brightness. At the same time, a gap between two adjacent convex lenses includes a curved groove on a side close to the convex lens, which can better gather light toward a central area of the convex lens, eliminate stray light and improve the lens gain. For example the first convex lens 41 can improve the effect of 1.2 to 1.8 times the brightness of the sub-pixel in which it is located.

In an exemplary implementation, the first lens portion 411 and the second lens portion 412 may have an integrated structure, and the first lens portion 411 and the second lens portion 412 may be fabricated using the same material by the same fabrication process. In some embodiments, the first lens portion and the second lens portion may be connected together using the same or different materials.

FIG. 6 is an enlarged view of a sectional structure of a light concentrating layer in a display substrate according to an exemplary embodiment of the present disclosure and may be a directional view at a in FIG. 5. In an exemplary implementation, as shown in FIGS. 5 and 6, a first gap 71 is included between the first convex lens 41 and the second convex lens 42. The first gap 71 includes a curved groove 82 on a side close to the first convex lens 41, which is recessed toward the inner side of the first convex lens 41. Through the curved groove 82, refracted bottom light can be collected to the maximum extent, and light can be gathered towards the central area of the convex lens through the curved groove 82 to eliminate stray light and improve lens gain.

In an exemplary implementation, as shown in FIG. 6, the following relationship is satisfied between the curvature radius R1 of the curved groove 82 and the curvature radius R2 of the first convex lens 41 on the same side: 4.5≤R2/R1≤15. Thus, the curved groove 82 can converge light toward the central area of the convex lens and improve the lens gain.

In an exemplary implementation, as shown in FIGS. 4 and 6, the curved groove 82 includes a bottom end 821, which is an end of the curved groove 82 on a side close to the base substrate. In the thickness direction of the base substrate, there is a maximum spacing L3 between the bottom end 821 of the curved groove 82 and an edge of the first convex lens 41 on the same side close to the base substrate, and there is a minimum spacing L1 between orthographic projections of the first convex lens 41 and the second convex lens 42 on the base substrate. The maximum spacing L3 is smaller than the minimum spacing L1, so that the bottom of the convex lens can collect light to the maximum extent and improve the lens gain.

In an exemplary implementation, an orthographic projection of the first gap 71 between the first convex lens 41 and the second convex lens 42 on the base substrate is located in an orthographic projection of the first overlap portion 34 on the base substrate, thereby ensuring that the light emitted from the first filter pattern 31 and the light emitted from the second filter pattern 32 are condensed via the first convex lens 41 and the second convex lens 42, respectively, and preventing the light emitted from the first filter pattern 31 and the light emitted from the second filter pattern 32 from emitting outside the first convex lens 41 and the second convex lens 42.

In an exemplary implementation, a second gap 72 is included between the second convex lens 42 and the third convex lens 43, and an orthographic projection of the second gap 72 between the second convex lens 42 and the third convex lens 43 on the base substrate is located in an orthographic projection of the second overlap portion 35 on the base substrate, thereby ensuring that light emitted from the second filter pattern 32 and light emitted from the third filter pattern 33 are condensed via the second convex lens 42 and the third convex lens 43, respectively, and avoiding light emitted from the second filter pattern 32 and light emitted from the third filter pattern 33 from emitting outside the second convex lens 42 and the third convex lens 43.

In an exemplary implementation, as shown in FIG. 5, the maximum thickness of the first convex lens 41 is the sum of the maximum thickness h4 of the first lens portion 411 and the maximum thickness h1 of the second lens portion 412. The maximum thickness of the first convex lens 41 is greater than the maximum thickness h2 of the second convex lens 42, and the maximum thickness of the first convex lens 41 is greater than the maximum thickness h3 of the third convex lens 43. For example, the difference between the maximum thickness of the first convex lens 41 and the maximum thickness h2 of the second convex lens 42 is from 0.4 microns to 0.6 microns, and the difference between the maximum thickness of the first convex lens 41 and the maximum thickness h3 of the third convex lens 43 is from 0.4 microns to 0.8 microns.

By increasing the maximum thickness of the first convex lens 41, a display substrate of an embodiment of the present disclosure can improve the light emitting intensity of the sub-pixel where the first convex lens 41 is located. For example, the light emitting intensity of the sub-pixel where the first convex lens 41 is located can be increased by 1.2 times to 1.8 times. Thus, the light emitting intensity of the first convex lens 41 is the same as or close to the light emitting intensity of the second convex lens 42 and the light emitting intensity of the third convex lens 43, so as to solve the problem that the light emitting intensity of the first sub-pixel (the sub-pixel where the first convex lens 41 is located) is low relative to the light emitting intensity of the second sub-pixel (the sub-pixel where the second convex lens 42 is located) and the third sub-pixel (the sub-pixel where the third convex lens 43 is located), resulting in uneven light emitting from the display substrate. The first convex lens 41 can compensate the light emitting intensity of the first sub-pixel.

For example, the first sub-pixel emits blue light, the second sub-pixel emits green light, and the third sub-pixel emits red light. The light intensity of the blue light emitted by the first filter pattern 51 is lower than the light intensity of the green light emitted by the second filter pattern 52 and the light intensity of the red light emitted by the third filter pattern 53, and the light intensity of the green light emitted by the second filter pattern 52 is substantially equal to the light intensity of the red light emitted by the third filter pattern 53. The maximum thickness h2 of the second convex lens 42 is substantially equal to the maximum thickness h3 of the third convex lens 43. The maximum thickness of the first convex lens 41 is greater than the maximum thickness h2 of the second convex lens 42, and the difference between the maximum thickness of the first convex lens 41 and the maximum thickness h2 of the second convex lens 42 is 0.4 microns. The maximum thickness of the first convex lens 41 is larger than the maximum thickness h3 of the third convex lens 43, and the difference between the maximum thickness of the first convex lens 41 and the maximum thickness h3 of the third convex lens 43 is 0.4 microns. The blue light emitted by the first filter pattern 51 is condensed via the first convex lens 41, so that the light intensity of the blue light emitted by the first sub-pixel is increased by 1.2 times, thereby make the light intensity of the blue light emitted by the first sub-pixel, the light intensity of the green light emitted by the second sub-pixel and the light intensity of the red light emitted by the third sub-pixel substantially equal.

In an exemplary implementation, an area of an orthographic projection of an opening area of the first sub-pixel on the base substrate is larger than an area of an orthographic projection of an opening area of the second sub-pixel on the base substrate, and the area of the orthographic projection of the opening area of the first sub-pixel on the base substrate is larger than an area of an orthographic projection of an opening area of the third sub-pixel on the base substrate. An area of an orthographic projection of the first convex lens 41 corresponding to the first sub-pixel on the base substrate is larger than an area of an orthographic projection of the second convex lens 42 corresponding to the second sub-pixel on the base substrate, and the area of the orthographic projection of the first convex lens 41 corresponding to the first sub-pixel on the base substrate is larger than an area of an orthographic projection of the third convex lens 43 corresponding to the third sub-pixel on the base substrate. For example, the difference between the area of an orthographic projection of the first convex lens 41 of the first sub-pixel on the base substrate and the area of an orthographic projection of the second convex lens 42 of the second sub-pixel on the base substrate is 5 μm² to 15 um². The difference between the area of an orthographic projection of the first convex lens 41 of the first sub-pixel on the base substrate and the area of an orthographic projection of the third convex lens 43 of the third sub-pixel on the base substrate is 5 μm² to 25 μm².

The display substrate of an embodiment of the present disclosure can make the light emitting intensity of the first convex lens 41 equal to or close to the light emitting intensity of the second convex lens 42 and the light emitting intensity of the third convex lens 43 by increasing the area of the orthographic projection of the first convex lens 41 on the base substrate, thereby enabling the first convex lens 41 to compensate the light emitting intensity of the first sub-pixel.

In some embodiments, at least one of the second convex lens and the third convex lens may have substantially the same structure as the first convex lens, i.e. at least one of the second convex lens and the third convex lens includes a third lens portion and a fourth lens portion stacked sequentially in a direction away from the base substrate. The fourth lens portion is hemispherical and has substantially the same structure as the first lens portion of the first convex lens, and the third lens portion has substantially the same structure as the second lens portion of the first convex lens.

FIG. 7 is a second schematic diagram of a sectional structure of a light concentrating layer in a display substrate according to an exemplary embodiment of the present disclosure. In an exemplary implementation, as shown in FIG. 7, a light concentrating layer of a display substrate of an exemplary embodiment of the present disclosure is substantially the same as that of the display substrate shown in FIG. 5, except that the structures of the second convex lens 42 and the third convex lens 43 are both substantially the same as the structure of the first convex lens 41. Specifically, the second convex lens 42 includes a third lens portion 421 and a fourth lens portion 422 which are sequentially stacked in a direction away from the base substrate, and the fourth lens portion 422 is hemispherical. The third convex lens 43 includes a fifth lens portion 431 and a sixth lens portion 432 stacked sequentially in a direction away from the base substrate, and the sixth lens portion 432 is hemispherical.

In an exemplary implementation, as shown in FIG. 7, in the same light emitting unit, the gaps between adjacent lenses each include curved grooves that are recessed toward one side of the lens. For example, the first gap 71 includes a curved groove 82 on a side close to the first convex lens 41 and the second convex lens 42, and the second gap 72 includes curved grooves 82 on a side close to the second convex lens 42 and on a side close to the third convex lens 43.

An exemplary embodiment of the present disclosure can collect the refracted bottom light to the maximum extent through the curved groove 82, and gather the light toward the central area of the convex lens through the curved groove 82, thus eliminating stray light and improving the lens gain.

An embodiment of the present disclosure further provides a method for manufacturing a display substrate, including: forming a light emitting device on a base substrate; forming a color film layer on the light emitting device, the color film layer including at least two filter patterns, at least portions of adjacent filter patterns being stacked in a thickness direction of the base substrate to form an overlap portion; and forming a light concentrating layer on the color film layer, the light concentrating layer being configured to concentrate light emitted from the color film layer.

The light concentrating layer includes at least two adjacent convex lenses, at least one of the two adjacent convex lenses includes a first lens portion and a second lens portion disposed sequentially in a direction away from the base substrate, and the second lens portion is hemispherical. Orthographic projections of the two adjacent convex lenses on the base substrate overlap with orthographic projections of different filter patterns on the base substrate. A gap is included between the two adjacent convex lenses, at least one gap includes a curved groove on a side close to the convex lens, and a gap between orthographic projections of the two adjacent convex lenses on the base substrate is located in an orthographic projection of the overlap portion on the base substrate.

The present disclosure further provides a display device, including the display substrate according to the aforementioned embodiments. The display device may be any product or component with a display function, such as a mobile phone, a tablet computer, a television, a display, a laptop computer, a digital photo frame, or a navigator.

In some embodiments, the display device of the present disclosure may be a VR or AR display device.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict.

Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate;
a light emitting device disposed on a side of the base substrate, the light emitting device being configured to emit light;
a color film layer disposed on a side of the light emitting device away from the base substrate, the color film layer comprising at least two filter patterns; at least portions of adjacent filter patterns being stacked in a thickness direction of the base substrate to form an overlap portion; and
a light concentrating layer disposed on a side of the color film layer away from the base substrate, the light concentrating layer being configured to concentrate light emitted from the color film layer;
wherein the light concentrating layer comprises at least two adjacent convex lenses, at least one of the two adjacent convex lenses comprises a first lens portion and a second lens portion disposed sequentially in a direction away from the base substrate, and the second lens portion is hemispherical, and wherein orthographic projections of the two adjacent convex lenses on the base substrate overlap with orthographic projections of different filter patterns on the base substrate; a gap is comprised between the two adjacent convex lenses, at least one gap comprises a curved groove on a side close to a convex lens, and a gap between the orthographic projections of the two adjacent convex lenses on the base substrate is located in an orthographic projection of the overlap portion on the base substrate.

2. The display substrate according to claim 1, wherein the following relationship is satisfied between a curvature radius R1 of the curved groove and a curvature radius R2 of the convex lens on the same side: 4.5≤R2/R1≤15.

3. The display substrate according to claim 1, wherein in the thickness direction of the base substrate, a minimum spacing between a bottom end of the curved groove and an edge of the convex lens on the same side is smaller than a minimum spacing between the orthographic projections of the two adjacent convex lenses on the base substrate.

4. The display substrate according to claim 1, wherein a minimum spacing L1 between the orthographic projections of the two adjacent convex lenses on the base substrate is less than or equal to 0.8 microns and greater than or equal to 0.2 microns.

5. The display substrate according to claim 1, wherein an orthographic projection of the gap between the two adjacent convex lenses on the base substrate is located in an orthographic projection of the overlap portion on the base substrate.

6. The display substrate according to claim 1, wherein the two adjacent convex lenses comprise a first convex lens and a second convex lens, the first convex lens comprising a first lens portion and a second lens portion disposed sequentially in a direction away from the base substrate, the second lens portion being hemispherical, the second convex lens comprising a circular bottom surface, the second convex lens having a maximum thickness less than or equal to a radius of the circular bottom surface.

7. The display substrate according to claim 6, wherein a maximum thickness of the first convex lens is greater than the maximum thickness of the second convex lens.

8. The display substrate according to claim 7, wherein the difference between the maximum thickness of the first convex lens and the maximum thickness of the second convex lens is from 0.4 microns to 0.6 microns.

9. The display substrate according to claim 6, wherein a maximum thickness of the first convex lens is 2.1 times to 2.5 times a radius of a bottom surface of the first convex lens on a side close to the base substrate.

10. The display substrate according to claim 1, wherein the two adjacent convex lenses comprise a first convex lens and a second convex lens, the first convex lens comprises a first lens portion and a second lens portion, the second convex lens comprises a third lens portion and a fourth lens portion disposed sequentially in a direction away from the base substrate, and the fourth lens portion is hemispherical.

11. The display substrate according to claim 1, wherein areas of the orthographic projections of the two adjacent convex lenses on the base substrate are different.

12. The display substrate according to claim 1, wherein the color film layer comprises a first filter pattern, a second filter pattern and a third filter pattern, and wherein the first filter pattern is adjacent to the second filter pattern, and at least a portion of the first filter pattern and at least a portion of the second filter pattern are stacked in a thickness direction of the base substrate to form a first overlap portion, in which the first filter pattern is located on a side of the second filter pattern away from the base substrate; the second filter pattern is adjacent to the third filter pattern, and at least a portion of the second filter pattern and at least a portion of the third filter pattern are stacked in the thickness direction of the base substrate to form a second overlap portion, in which the second filter pattern is located on a side of the third filter pattern away from the base substrate.

13. The display substrate according to claim 1, wherein the first lens portion and the second lens portion are of an integral structure.

14. The display substrate according to claim 1, wherein the first lens portion comprises a first surface on a side close to the base substrate, a second surface on a side away from the base substrate, and a side surface connecting the first surface and the second surface, the second surface is a surface of the second lens portion on a side close to the base substrate, and the side surface is arc-shaped.

15. The display substrate according to claim 14, wherein an included angle between a tangent at an intersection of the side surface and the first surface and a plane parallel to the base substrate is less than 90 degrees and greater than or equal to 30 degrees.

16. The display substrate according to claim 14, wherein a distance between the first surface of the first lens portion and the second surface of the first lens portion is from 300 nm to 600 nm.

17. The display substrate according to claim 1, further comprising a flat layer positioned between the color film layer and the light concentrating layer, wherein a refractive index of a material of the flat layer is not greater than that of a material of the light concentrating layer.

18. The display substrate according to claim 1, wherein a maximum thickness of the second lens portion is greater than a maximum thickness of the first lens portion in a direction perpendicular to the base substrate; or
wherein a minimum distance between the orthographic projections of the two adjacent convex lenses on the base substrate is greater than or equal to a maximum thickness of the first lens portion.

19. (canceled)

20. A display device, comprising the display substrate according to claim 1.

21. A preparation method for a display substrate, comprising:
forming a light emitting device on a base substrate;
forming a color film layer on the light emitting device, wherein the color film layer comprises at least two filter patterns; at least portions of adjacent filter patterns are stacked in a thickness direction of the base substrate to form an overlap portion; and
forming a light concentrating layer on the color film layer, the light concentrating layer being configured to concentrate light emitted from the color film layer;
wherein the light concentrating layer comprises at least two adjacent convex lenses, at least one of the two adjacent convex lenses comprises a first lens portion and a second lens portion disposed sequentially in a direction away from the base substrate, and the second lens portion is hemispherical, and wherein orthographic projections of the two adjacent convex lenses on the base substrate overlap with orthographic projections of different filter patterns on the base substrate; a gap is comprised between the two adjacent convex lenses, at least one gap comprises a curved groove on a side close to a convex lens, and a gap between the orthographic projections of the two adjacent convex lenses on the base substrate is located in an orthographic projection of the overlap portion on the base substrate.
